(19) United States
(12) Patent Application Publication
(10) Pub. No.: US 2025/0285665 A1
(43) Pub. Date: Sep. 11, 2025

(54) MEMORY DEVICE, AN OPERATING METHOD OF THE MEMORY DEVICE, AND A MEMORY MODULE INCLUDING THE MEMORY DEVICE

(71) Applicant: SAMSUNG ELECTRONICS CO., LTD., SUWON-SI (KR)

(72) Inventors: YongHyun AN, Suwon-si (KR); Dahui KIM, Suwon-si (KR)

(21) Appl. No.: 18/830,733

(22) Filed: Sep. 11, 2024

(30) Foreign Application Priority Data
Mar. 6, 2024 (KR) 10-2024-0031720

(51) Int. Cl. G11C 7/10; G06F 3/06; G11C 7/22; H03K 19/20

(52) U.S. Cl. CPC G11C 7/1096; G06F 3/0619; G06F 3/0659; G06F 3/0673; G11C 7/222; H03K 19/20

(57) ABSTRACT

A memory device including: a command decoder to receive a write command signal in synchronization with a clock signal and generate a write leveling pulse signal in response to the write command signal and in synchronization with the clock signal in a write leveling operation; a first write circuit to receive a first data strobe signal at a first location on a data strobe signal path, first sample the write leveling pulse signal in synchronization with the first data strobe signal in the write leveling operation, and output a first write leveling signal; and a second write circuit to receive a second data strobe signal at a second location on the data strobe signal path, second sample the write leveling pulse signal in synchronization with the second data strobe signal in the write leveling operation, and output a second write leveling signal.

### CROSS-REFERENCE TO RELATED APPLICATION

This application claims priority under 35 U.S.C. § 119 to Korean Patent Application No. 10-2024-0031720 filed on Mar. 6, 2024, in the Korean Intellectual Property Office, the disclosure of which is incorporated by reference herein in its entirety.

### Technical Field

Embodiments of the present disclosure relate to an electronic device, and more particularly, to a memory device that performs a write leveling operation with improved reliability, an operating method of the memory device, and a memory module including the memory device.

### Discussion of Related Art

A memory device is used to store data in computing devices such as computers, smartphones, and tablets. As industries related to these computing devices evolve, the performance demands on memory devices have also risen. One key performance requirement for memory devices is communication speed. As the overall performance expectations for memory devices grow, so does the demand for higher communication speeds.

To meet the demand for increased communication speeds in memory devices, the frequency of the signal used for communication with a host device can be increased. However, operating at higher communication frequencies may impair the memory device's ability to accurately receive signals at the correct timing, potentially reducing the reliability of the communication.

### SUMMARY

Embodiments of the present disclosure provide a memory device designed to enhance reliability by achieving more accurate timing in receiving communication signals, an operating method of the memory device, and a memory module including the memory device.

According to an embodiment of the present disclosure, there is provided a memory device including: a memory cell array including a plurality of memory cells; a command decoder configured to receive a write command signal from a host device in synchronization with a clock signal received from the host device and to generate a write leveling pulse signal in response to the write command signal and in synchronization with the clock signal in a write leveling operation; a data strobe signal path configured to transfer a data strobe signal received from the host device; a first write circuit configured to receive a first data strobe signal at a first location on the data strobe signal path, to first sample the write leveling pulse signal in synchronization with the first data strobe signal in the write leveling operation, and to output a first write leveling signal based on the first sampling; and a second write circuit configured to receive a second data strobe signal at a second location on the data strobe signal path, to second sample the write leveling pulse signal in synchronization with the second data strobe signal in the write leveling operation, and to output a second write leveling signal based on the second sampling, wherein, in the write leveling operation, the memory device is configured to generate a feedback signal to be sent to the host device based on the first write leveling signal and the second write leveling signal.

According to an embodiment of the present disclosure, there is provided an operating method of a memory device, the method including: performing, at the memory device, a first write leveling operation to align a timing between a clock signal and a data strobe signal received from a host device; and performing, at the memory device, a second write leveling operation to align a timing between an internal clock signal path through which the clock signal is transferred and an internal data strobe signal path through which the data strobe signal is transferred, wherein the second write leveling operation is performed based on internal data strobe signals obtained at two or more locations on the internal data strobe signal path.

According to an embodiment of the present disclosure, there is provided a memory module including: a plurality of memory devices each configured to receive a data signal and a data strobe signal from a host device; and a register clock driver configured to receive a clock signal from the host device and to provide the clock signal to the plurality of memory devices, wherein each of the plurality of memory devices is configured to: perform a first write leveling operation to align a timing of the clock signal provided from the register clock driver and a timing of the data strobe signal provided from the host device; and perform a second write leveling operation to align a timing between an internal clock signal path through which the clock signal is transferred and an internal data strobe signal path through which the data strobe signal is transferred, and wherein the second write leveling operation is performed based internal data strobe signals obtained at two or more locations on the internal data strobe signal path.

### BRIEF DESCRIPTION OF THE DRAWINGS

The above and other features of the present disclosure will become apparent by describing in detail embodiments thereof with reference to the accompanying drawings.

FIG. 1 illustrates a computing device according to an embodiment of the present disclosure.

FIG. 2 illustrates a memory module according to an embodiment of the present disclosure.

FIG. 3 illustrates an example of a method in which a computing device performs a write leveling operation, according to an embodiment of the present disclosure.

FIG. 4 illustrates a memory device according to an embodiment of the present disclosure.

FIG. 5 illustrates a first write circuit according to an embodiment of the present disclosure.

FIG. 6 illustrates an example of a method in which a memory device of FIG. 5 performs a location-selective internal write leveling operation.

FIG. 7 illustrates a memory device according to an embodiment of the present disclosure.

FIG. 8 illustrates an example of a method in which a memory device of FIG. 7 performs a location-selective internal write leveling operation.

FIG. 9 illustrates a memory device according to an embodiment of the present disclosure.

FIG. 10 illustrates an example of a method in which a memory device of FIG. 9 performs a location-selective internal write leveling operation.

FIG. 11 illustrates a memory device according to an embodiment of the present disclosure.

FIG. 12 illustrates an example of a method in which a memory device of FIG. 11 performs a location-selective internal write leveling operation.

FIG. 13 illustrates an example of an operating method of a host device and a memory device.

### DETAILED DESCRIPTION OF THE EMBODIMENTS detail and with clarity, enabling those skilled in the art to readily implement the disclosure.

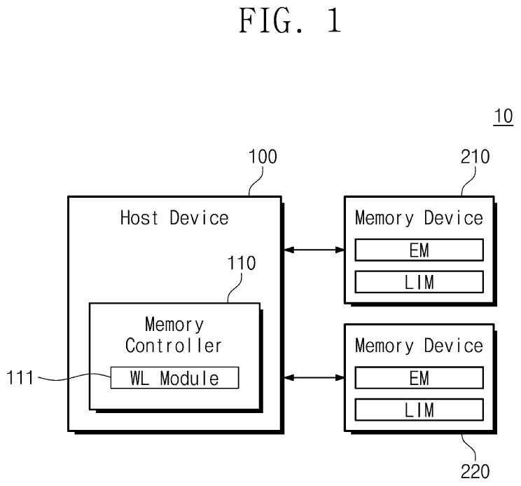

The following sections will describe embodiments of the present disclosure in FIG. 1 illustrates a computing device 10 according to an embodiment of the present disclosure. Referring to FIG. 1, the computing device 10 may include a host device 100, a first memory device 210, and a second memory device 220.

The host device 100 may include a central processing unit (CPU) or an application processor (AP). The host device 100 may further include a hardware accelerator such as a graphics processing unit (GPU) or a neural processing unit (NPU). The host device 100 may execute an operating system and various applications. The host device 100 may include various devices such as a modem for communicating with an external device, a storage device for storing data in a nonvolatile manner, and a user interface for communicating with a user.

The host device 100 may include a memory controller 110. The memory controller 110 may control the first memory device 210 and the second memory device 220 and may access the first memory device 210 and the second memory device 220. The memory controller 110 may be implemented in hardware as a circuit.

The memory controller 110 may include a write leveling module 111. The write leveling module 111 may be implemented in hardware as a circuit. The write leveling module 111 may perform write leveling for each of the first memory device 210 and the second memory device 220. The write leveling operation may include adjusting the following during a write operation performed by the memory controller 110 on each of the first memory device 210 and the second memory device 220: the timing at which each of the first and second memory devices 210 and 220 latches (or captures) a data signal from the memory controller 110, and the timing for executing the write operation.

Each of the first memory device 210 and the second memory device 220 may include an external write leveling module EM and a location-selective internal write leveling module LIM. Each of the external write leveling module EM and the location-selective internal write leveling module LIM may be implemented in hardware as a circuit.

The external write leveling module EM may perform external write leveling under control of the write leveling module 111 of the memory controller 110. This operation aims to align any timing differences caused by external factors affecting the first memory device 210 and the second memory device 220.

The location-selective internal write leveling module LIM may address timing differences caused by internal factors within the first memory device 210 and the second memory device 220. The location-selective internal write leveling module LIM supports an internal write leveling operation based on signals obtained from two or more locations along internal signal paths. By performing the internal write leveling operation based on these signals, the reliability of the operation can be enhanced, leading to more accurate timing for data acquisition by each of the first memory device 210 and the second memory device 220.

The write leveling module 111 of the memory controller 110 may perform external write leveling and location-selective internal write leveling operations for each of the first memory device 210 and the second memory device 220. For example, these operations can be conducted either sequentially or simultaneously. The write leveling operation may include both the external write leveling and location-selective internal write leveling operations.

In an embodiment, the first memory device 210 or the second memory device 220 may be connected to the host device 100 along with another memory device (hereinafter referred to as a “non-support memory device”) that does not support the location-selective internal write leveling operation. The write leveling module 111 may perform the external write leveling operation on the first memory device 210 or the second memory device 220 and the non-support memory device in the same manner.

The write leveling module 111 may perform the location-selective internal write leveling operation on the first memory device 210 or the second memory device 220. For the non-support memory device, which does not support this feature, the write leveling module 111 may instead perform a standard internal write leveling operation, such as one based on a signal obtained from a single location. As another example, the write leveling module 111 may perform a standard write leveling operation on the non-support memory device, along with a standard internal write leveling operation on the first memory device 210 or the second memory device 220.

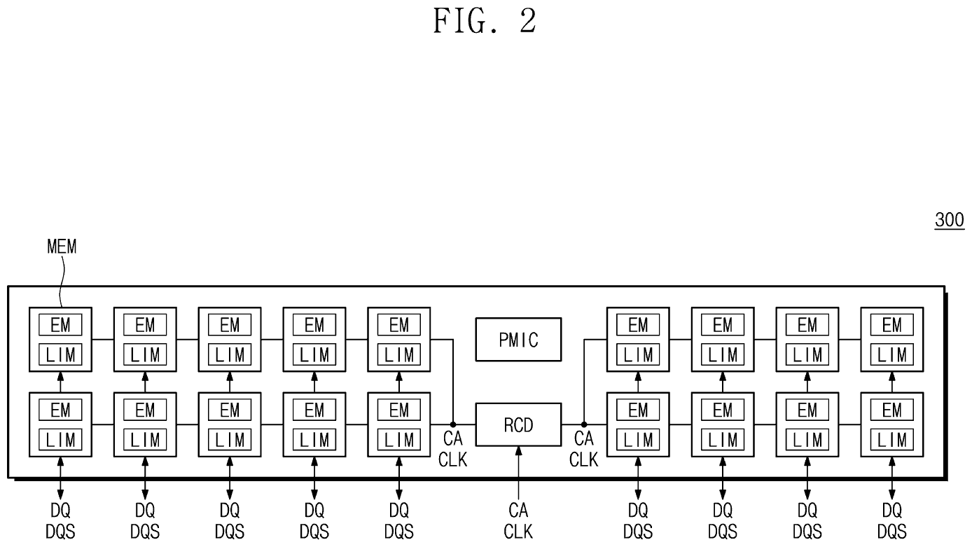

FIG. 2 illustrates a memory module 300 according to an embodiment of the present disclosure. Referring to FIGS. 1 and 2, the memory module 300 may include memory devices MEM, a register clock driver RCD (implemented in hardware as a circuit), and a power management device PMIC.

Each of the memory devices MEM may communicate data signals DQ and a data strobe signal DQS with an external device. Each of the memory devices MEM may latch (or capture) the data signal DQ by using the data strobe signal DQS. An example is illustrated where the memory devices MEM are arranged in the matrix with two rows and nine columns, but the number and arrangement of memory devices MEM are not limited to this configuration.

Each of the memory devices MEM may include the external write leveling module EM and the location-selective internal write leveling module LIM. The host device 100 may perform the external write leveling and location-selective internal write leveling operations for each of the memory devices MEM.

The register clock driver RCD may receive a command and address CA and a clock signal CK from the external device. The register clock driver RCD may provide the command and address CA and the clock signal CK to the memory devices MEM in common.

Each of the memory devices MEM may latch (or capture) the command and address CA by using the clock signal CK. Each of the memory devices MEM may select a timing to perform an operation requested by the command and address CA based on the clock signal CK.

The power management device PMIC may receive an input voltage from the external device. The power management device PMIC may convert the input voltage into an output voltage. The power management device PMIC may provide the output voltage to the memory devices MEM in common. The power management device PMIC may provide the output voltage to the register clock driver RCD or may provide another output voltage, converted from the input voltage, to the register clock driver RCD.

In an embodiment, the memory module 300 may correspond to one of the first memory device 210 and the second memory device 220 described with reference to FIG. 1. Alternatively, each of the memory devices MEM of the memory module 300 may correspond to one of the first memory device 210 and the second memory device 220 described with reference to FIG. 1.

The host device 100 may perform the external write leveling and location-selective internal write leveling operations on the memory devices MEM simultaneously or sequentially.

As illustrated in FIGS. 1 and 2, the data signal DQ and the data strobe signal DQS may be directly transferred from the host device 100 to the memory devices MEM. The clock signal CK and the command and address CA are transferred to the memory devices MEM from the host device 100 through the register clock driver RCD.

The paths on the memory module 300, through which the command and address CA and the clock signal CK are transferred, may vary in length among the memory devices MEM. This variation in path length can cause the timing of the arrival of the clock signal CK and the command and address CA at the memory devices MEM to be inconsistent.

The external write leveling operation may align (or correct) the timing differences caused by external factors affecting the memory devices MEM. For example, by performing the external write leveling operation, the host device 100 may adjust the timing for sending the data signal DQ and the data strobe signal DQS so that the data signal DQ, the data strobe signal DQS, the clock signal CK, and the command and address CA arrive at each of the memory devices MEM simultaneously and in synch.

In an embodiment, the memory module 300 may communicate with the external device using a dual in-line memory module (DIMM), a registered DIMM (RDIMM), or a load-reduced DIMM (LRDIMM) configuration.

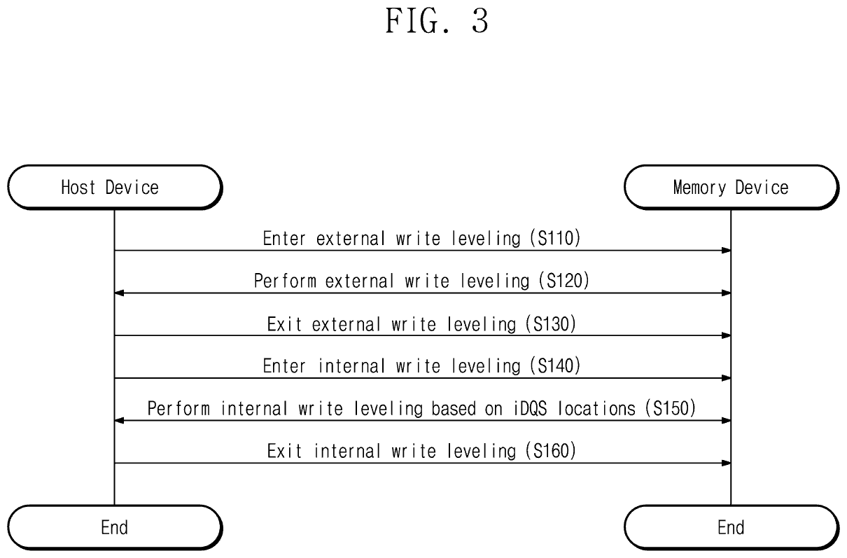

FIG. 3 illustrates an example of a method in which the computing device 10 performs a write leveling operation, according to an embodiment of the present disclosure. Referring to FIGS. 1, 2, and 3, in operation S110, operation S120, and operation S130, the computing device 10 may perform the external write leveling operation.

In operation S110, the host device 100 may request the memory devices MEM to enter the external write leveling operation. For example, the memory controller 110 of the host device 100 may enter the external write leveling operation by programming second mode registers of the memory devices MEM. For example, the memory controller 110 may enter the external write leveling operation by programming “1” (=MR2:OP[1]) in the second mode registers MR2 of the memory devices MEM.

In operation S120, the host device 100 and the memory device MEM may perform the external write leveling operation. The host device 100 may send the command and address CA indicating the write operation, the clock signal CK, and the data strobe signal DQS to the memory devices MEM. In an embodiment, the host device 100 may send a write preamble along with a signal that toggles by an amount corresponding to a portion of the burst length, as the data strobe signal DQS. For example, the host device 100 may send a signal that includes the write preamble and a single toggle as the data strobe signal DQS.

The memory devices MEM may detect whether the high level of the clock signal CK is latched (or captured) by the rising edge (or falling edge) of the data strobe signal DQS.

For example, the memory devices MEM may generate a write leveling pulse signal based on the command and address CA and the clock signal CK. The memory devices MEM may output the level of the write leveling pulse signal latched (or captured) by the rising edge (or falling edge) of the data strobe signal DQS as the data signals DQ (e.g., as a feedback signal).

Until the high level of the write leveling pulse signal is detected from the memory devices MEM, the memory controller 110 may repeat the following while sweeping the data strobe signal DQS: sending the command and address CA, the data strobe signal DQS, and the clock signal CK to the memory devices MEM and receiving the feedback signal from the memory devices MEM. When the high level of the write leveling pulse signal is detected from the memory devices MEM, the memory controller 110 may add (or subtract) an offset (e.g., a ¼ of the period of the data strobe signal DQS) to (or from) the detected high level timing from the memory devices MEM and then determine the corresponding timing of the data strobe signal DQS for each of the memory devices MEM.

In operation S130, the host device 100 may request the memory devices MEM to exit the external write leveling operation. For example, the memory controller 110 may exit the external write leveling operation by programming “0” (=MR2:OP[1]) in the second mode registers MR2 of the memory devices MEM.

In operation S140, operation S150, and operation S160, the computing device 10 may perform the location-selective internal write leveling operation.

In operation S140, the host device 100 may request the memory devices MEM to enter the location-selective internal write leveling operation. For example, the memory controller 110 of the host device 100 may enter the internal write leveling operation by programming the second mode registers MR2 of the memory devices MEM. For example, the memory controller 110 may enter the internal write leveling operation by programming “1” (=MR2:OP[7]) in the second mode registers MR2 of the memory devices MEM.

In operation S150, the host device 100 and the memory device MEM may perform the internal write leveling operation based on an internal data strobe signal iDQS. For example, the host device 100 and the memory device MEM may perform the location-selective internal write leveling operation.

The host device 100 can set the delay amount for the write leveling pulse signal in the memory devices MEM by programming third mode registers MR3 of the memory devices MEM. For example, the host device 100 may set the write leveling pulse signal delay by programming write leveling internal cycle alignment (WICA) settings of the third mode registers MR3 of the memory devices MEM.

The host device 100 may send the command and address CA indicating the write operation, the clock signal CK, and the data strobe signal DQS to the memory devices MEM. In an embodiment, the host device 100 may send a write preamble along with a signal that toggles by an amount corresponding to a portion of the burst length, as the data strobe signal DQS. For example, the host device 100 may send a signal that includes the write preamble and a single toggle as the data strobe signal DQS.

The memory devices MEM may internally use the received data strobe signal DQS as the internal data strobe signal iDQS. The memory devices MEM may detect whether the high level of the clock signal CK is latched (or captured) by the rising edge (or falling edge) of the internal data strobe signal iDQS, at two or more locations along an internal data strobe signal path through which the internal data strobe signal iDQS is transferred.

For example, the memory devices MEM may generate the write leveling pulse signal based on the command and address CA and the clock signal CK. The memory devices MEM may output the level of the write leveling pulse signal latched (or captured) by the rising edge (or falling edge) of the internal data strobe signal iDQS as the data signals DQ (e.g., as a feedback signal).

Until the high level of the write leveling pulse signal is detected from the memory devices MEM, the memory controller 110 may repeat the following while sweeping the delay amount of the write leveling pulse signal, which is stored in the third mode registers MR3 of the memory devices MEM: sending the command and address CA, the data strobe signal DQS, and the clock signal CK to the memory devices MEM and receiving the feedback signal from the memory devices MEM. When the high level of the write leveling pulse signal is detected from all of the memory devices MEM, the memory controller 110 may program a delay amount obtained by adding (or subtracting) an offset (e.g., a ¼ of the period of the data strobe signal DQS) to (or from) the detected high level timing, in the third mode register MR3 of each of the memory devices MEM, as the WICA setting.

In operation S160, the host device 100 may request the memory devices MEM to exit the internal write leveling operation. For example, the memory controller 110 may exit the internal write leveling operation by programming “0” (=MR2:OP[7]) in the second mode registers MR2 of the memory devices MEM.

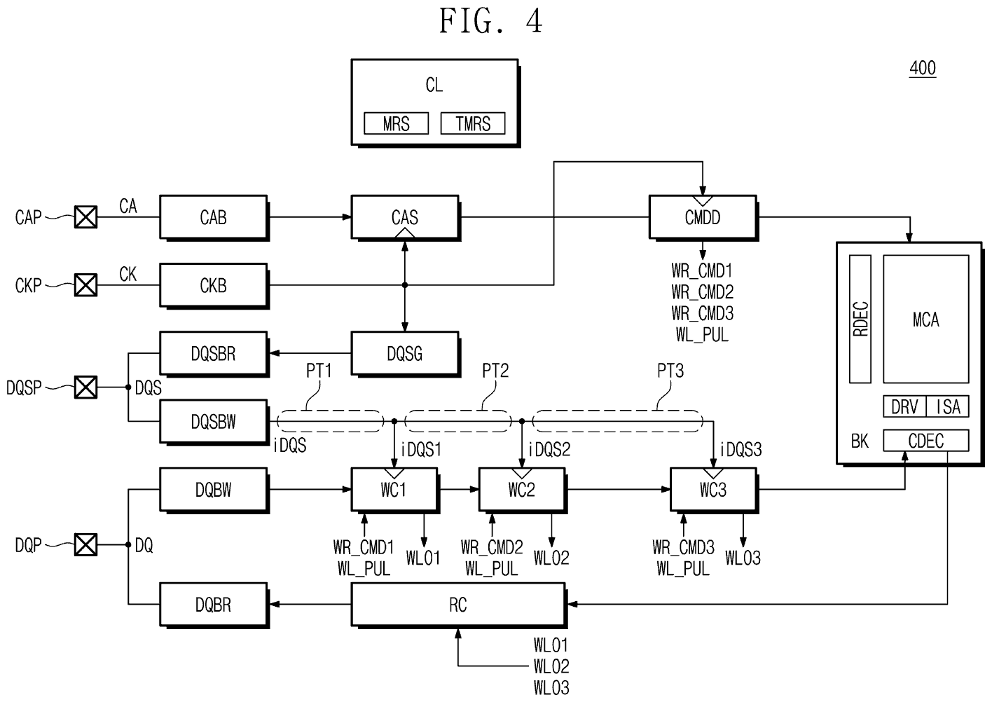

FIG. 4 illustrates a memory device 400 according to an embodiment of the present disclosure. In an embodiment, the memory device 400 may correspond to one of the first memory device 210 and the second memory device 220 of FIG. 1 or one of the memory devices MEM of the memory module 300 of FIG. 2.

Referring to FIGS. 1 and 4, the memory device 400 may include a command and address pad CAP, a clock signal pad CKP, a data strobe signal pad DQSP, and a data signal pad DQP. The command and address pad CAP may receive the command and address CA from the host device 100. The clock signal pad CKP may receive the clock signal CK from the host device 100. The data strobe signal pad DQSP may receive the data strobe signal DQS from the host device 100 or may send the data strobe signal DQS to the host device 100. The data signal pad DQP may receive the data signal DQ from the host device 100 or may send the data signal DQ to the host device 100.

The memory device 400 may further include a command and address buffer CAB, a clock buffer CKB, a command and address sampler CAS, and a command decoder CMDD, each of which being implemented in hardware as a circuit. The command and address buffer CAB may buffer the command and address CA received through the command and address pad CAP. The clock buffer CKB may buffer the clock signal CK received through the clock signal pad CKP. The command and address sampler CAS may sample the command and address CA output from the command and address buffer CAB in synchronization with the clock signal CK output from the clock buffer CKB.

The command decoder CMDD may receive the command and address CA sampled by the command and address sampler CAS. The command decoder CMDD may output various command signals (e.g., pulse signals) for controlling operations of the memory device 400, based on the sampled command and address CA.

In particular, when the sampled command and address CA indicates the write operation, the command decoder CMDD may output a first write command WR_CMD1, a second write command WR_CMD2, and a third write command WR_CMD3. The first write command WR_CMD1, the second write command WR_CMD2, and the third write command WR_CMD3 may be signals that transition at different times, for example, these signal have different column write latencies (CWLs).

In the external write leveling operation or the location-selective internal write leveling operation, when the sampled command and address CA indicates the write operation, the command decoder CMDD may output a write leveling pulse signal WL_PUL. The write leveling pulse signal WL_PUL may be a pulse signal that transitions at a default timing and reaches the high level, for example, at CWL0, CWL1, and CWL2.

The memory device 400 may further include a data strobe signal generator DQSG, a read data strobe buffer DQSBR, and a write data strobe buffer DQSBW, each of which being implemented in hardware as a circuit. After the command and address CA indicating the read operation is received, the data strobe signal generator DQSG may generate the data strobe signal DQS based on the clock signal CK output from the clock buffer CKB at a specified timing. The read data strobe buffer DQSBR may then buffer the data strobe signal DQS output from the data strobe signal generator DQSG and may output the data strobe signal DQS to the host device 100 through the data strobe signal pad DQSP.

For example, in the write operation or the write leveling operation, the write data strobe buffer DQSBW may receive the data strobe signal DQS from the host device 100 through the data strobe signal pad DQSP. The write data strobe buffer DQSBW may buffer the data strobe signal DQS and may send the internal data strobe signal iDQS to an internal data strobe signal path. For example, the internal data strobe signal path may include a first path PT1, a second path PT2 following the first path PT1, and a third path PT3 following the second path PT2. In an embodiment, the internal data strobe signal path may include one or more buffers configured to buffer the internal data strobe signal iDQS.

The memory device 400 may further include a write data buffer DQBW (implemented in hardware as a circuit), a first write circuit WC1, a second write circuit WC2, a third write circuit WC3, a bank BK (implemented in hardware as a circuit), a read circuit RC, and a read data buffer DQBR (implemented in hardware as a circuit).

The write data buffer DQBW may receive the data signal DQ from the host device 100 through the data signal pad DQP. The write data buffer DQBW may transfer the data signal DQ to the first write circuit WC1.

The first write circuit WC1 may receive the first write command WR_CMD1 and the write leveling pulse signal WL_PUL from the command decoder CMDD. For example, in the write operation, the first write circuit WC1 may receive the first write command WR_CMD1 from the command decoder CMDD. In the write leveling operation, the first write circuit WC1 may receive the write leveling pulse signal WL_PUL from the command decoder CMDD.

The first write circuit WC1 may receive a first internal data strobe signal iDQS1 obtained at a location where the internal data strobe signal iDQS passes through the first path PT1. In other words, the first write circuit WC1 may receive the first internal data strobe signal iDQS1 generated at a point where the internal data strobe signal iDQS traverses the first path PT1. The first write circuit WC1 may sample the data signal DQ transferred from the write data buffer DQBW, in synchronization with the first internal data strobe signal iDQS1, in response to the first write command WR_CMD1 or the write leveling pulse signal WL_PUL. For example, the first write circuit WC1 may latch (or capture) the data signal DQ output from the write data buffer DQBW at the rising edge (or falling edge) of the first internal data strobe signal iDQS1, in response to the rising edge (or falling edge) of the first write command WR_CMD1 or the write leveling pulse signal WL_PUL.

In the write operation, the first write circuit WC1 may support the write operation for writing the data signal DQ in the bank BK. For example, the first write circuit WC1 may perform various operations to support the write operation, including the removing or suppressing noise on the data signal DQ, realigning the timing of the data signal DQ, decoding the data signal DQ, initializing (or preparing) the path through which the data signal DQ is transferred, or serializing the data signal DQ. The first write circuit WC1 may output the processed data signal DQ to the second write circuit WC2.

In the external write leveling operation, the first write circuit WC1 may sample the write leveling pulse signal WL_PUL and output the result as a first write leveling output signal WLO1 in synchronization with the first internal data strobe signal iDQS1.

In the location-selective internal write leveling operation, the first write circuit WC1 may sample the write leveling pulse signal WL_PUL and output the result as the first write leveling output signal WLO1 in synchronization with the first internal data strobe signal iDQS1.

The second write circuit WC2 may receive a second internal data strobe signal iDQS2 obtained at a location where the internal data strobe signal iDQS passes through the second path PT2 following the first path PT1. In other word, the second write circuit WC2 may receive the second internal data strobe signal iDQS2 obtained at a point where the internal data strobe signal iDQS passes through the second path PT2, which follows the first path PT1. The second write circuit WC2 may sample the data signal DQ transferred from the first write circuit WC1, in synchronization with the second internal data strobe signal iDQS2, in response to the second write command WR_CMD2 or the write leveling pulse signal WL_PUL. For example, the second write circuit WC2 may latch (or capture) the data signal DQ output from the first write circuit WC1 at the rising edge (or falling edge) of the second internal data strobe signal iDQS2, in response to the rising edge (or falling edge) of the second write command WR_CMD2 or the write leveling pulse signal WL_PUL.

In the write operation, the second write circuit WC2 may support the write operation for writing the data signal DQ in the bank BK. For example, the second write circuit WC2 may perform various operations to support the write operation, including removing or suppressing noise on the data signal DQ, realigning the timing of the data signal DQ, decoding the data signal DQ, initializing (or preparing) the path through which the data signal DQ is transferred, or serializing the data signal DQ. The second write circuit WC2 may output the processed data signal DQ to the third write circuit WC3.

In the location-selective internal write leveling operation, the second write circuit WC2 sample the write leveling pulse signal WL_PUL and output the result as a second write leveling output signal WLO2 in synchronization with the second internal data strobe signal iDQS2.

The third write circuit WC3 may receive a third internal data strobe signal iDQS3 obtained at a location where the internal data strobe signal iDQS passes through the third path PT3 following the first path PT1 and the second path PT2. In other words, the third write circuit WC3 may receive the third internal data strobe signal iDQS3 at a point where the internal data strobe signal iDQS passes through the third path PT3, following the first path PT1 and the second path PT2. The third write circuit WC3 may sample the data signal DQ transferred from the second write circuit WC2, in synchronization with the third internal data strobe signal iDQS3, in response to the third write command WR_CMD3 or the write leveling pulse signal WL_PUL. For example, the third write circuit WC3 may latch (or capture) the data signal DQ output from the second write circuit WC2 at the rising edge (or falling edge) of the third internal data strobe signal iDQS3, in response to the rising edge (or falling edge) of the third write command WR_CMD3 or the write leveling pulse signal WL_PUL.

In the write operation, the third write circuit WC3 may support the write operation for writing the data signal DQ in the bank BK. For example, the third write circuit WC3 may perform various operations to support the write operation, including removing or suppressing noise on the data signal DQ, realigning the timing of the data signal DQ, decoding the data signal DQ, initializing (or preparing) a path through which the data signal DQ is transferred, or serializing the data signal DQ. The third write circuit WC3 may output the processed data signal DQ to the bank BK.

In the location-selective internal write leveling operation, the third write circuit WC3 may sample the write leveling pulse signal WL_PUL and output the result as a third write leveling output signal WLO3 in synchronization with the third internal data strobe signal iDQS3.

The bank BK may be used to store data. The bank BK may include a memory cell array MCA, a row decoder RDEC, a write driver DRV, a sense amplifier ISA, and a column decoder CDEC.

The memory cell array MCA may include a plurality of memory cells arranged in rows and columns. The row decoder RDEC may be connected to the rows of the memory cells and may select a row of memory cells. The write driver DRV may be connected to the columns of the memory cells and may write data in the memory cells of the row selected by the row decoder RDEC. The sense amplifier ISA may be connected to the columns of the memory cells and may read data from the memory cells of the row selected by the row decoder RDEC.

The column decoder CDEC may be connected to the columns of the memory cells and may select a column of memory cells. The column decoder CDEC may provide the write driver DRV of the selected column with the data signal DQ transferred from the third write circuit WC3. The column decoder CDEC may output the data stored in the sense amplifier ISA of the selected column.

In an embodiment, the bank BK may operate in response to a command transferred from the command decoder CMDD. For example, the bank BK may operate in response to the first write command WR_CMD1, the second write command WR_CMD2, the third write command WR_CMD3, or at least one of command signals whose timings are different from timings of the first write command WR_CMD1, the second write command WR_CMD2, and the third write command WR_CMD3.

In an embodiment, one bank BK is illustrated in FIG. 4, but the memory device 400 may include two or more banks. The memory device 400 may include two or more bank groups, and each bank group may include two or more banks. A bank group and a bank may be respectively identified by a bank group address and a bank address of the command and address CA.

In an embodiment, at least one of the first write circuit WC1, the second write circuit WC2, and the third write circuit WC3 may be included in the bank BK. At least one of the first write circuit WC1, the second write circuit WC2, and the third write circuit WC3 may be implemented with at least one of the row decoder RDEC, the write driver DRV, the sense amplifier ISA, and the column decoder CDEC or with a part of at least one thereof.

In the read operation, the read circuit RC may receive the data signal DQ output from the column decoder CDEC. The read circuit RC may perform various operations supporting the read operation, such as an operation of parallelizing the data signal DQ or an operation of performing pre-emphasis for the data signal DQ.

In the external write leveling operation, the read circuit RC may receive the first write leveling output signal WLO1 from the first write circuit WC1. The read circuit RC may transfer the first write leveling output signal WLO1 to the read data buffer DQBR. In other words, in the external write leveling operation, the memory device 400 may generate the write leveling pulse signal WL_PUL by using the command decoder CMDD and may sample the write leveling pulse signal WL_PUL in synchronization with the first internal data strobe signal iDQS1 by using the first write circuit WC1. The memory device 400 may output the first write leveling output signal WLO1, which is a result of the sampling, to the host device 100 through the data signal pad DQP.

In other words, in the external write leveling operation, the host device 100 and the memory device 400 may align (or synchronize) the timing of the arrival of the write leveling pulse signal WL_PUL and the first internal data strobe signal iDQS1 at the first write circuit WC1. In the external write leveling operation, because the write leveling pulse signal WL_PUL is synchronized with the clock signal CK, the host device 100 and the memory device 400 align the clock signal CK and the first internal data strobe signal iDQS1 in the first write circuit WC1. When the external write leveling operation is completed, the host device 100 may align the clock signal CK and the data strobe signal DQS by adding (or subtracting) an offset to (or from) the aligned timing to output the data strobe signal DQS to the memory device 400.

In the location-selective internal write leveling operation, the read circuit RC may output one of the first write leveling output signal WLO1, the second write leveling output signal WLO2, and the third write leveling output signal WLO3 to the read data buffer DQBR.

The memory device 400 may further include control logic CL (implemented in hardware as a circuit). The control logic CL may control operations of the memory device 400. The control logic CL may include a mode register set MRS and a test mode register set TMRS. The mode register set MRS may include a plurality of registers for setting operation modes of the memory device 400. For example, the mode register set MRS may include the second mode register MR2 and the third mode register MR3 described above. The test mode register set TMRS may include a plurality of test mode registers for setting pieces of information to perform a test.

In an embodiment, the first internal data strobe signal iDQS1 passes through the first path PT1 from the write data strobe buffer DQSBW. Compared to the data strobe signal DQS, the first internal data strobe signal iDQS1 may have a delay correspond to the time it takes to traverse the first path PT1.

The second internal data strobe signal iDQS2 passes through the first path PT1 and the second path PT2 from the write data strobe buffer DQSBW. Compared to the first internal data strobe signal iDQS1, the second internal data strobe signal iDQS2 may have a delay corresponding to the times it takes to traverse the second path PT2.

The third internal data strobe signal iDQS3 passes through the first path PT1, the second path PT2, and the third path PT3 from the write data strobe buffer DQSBW. Compared to the first internal data strobe signal iDQS1, the third internal data strobe signal iDQS3 may have a delay corresponding to the time it takes to traverse both the second path PT2 and the third path PT3. Additionally, compared to the second internal data strobe signal iDQS2, the third internal data strobe signal iDQS3 may have a delay corresponding to the time it takes to traverse the third path PT3.

As the frequency of the data strobe signal DQS increases and its period decreases, the differences in delay between the first internal data strobe signal iDQS1, the second internal data strobe signal iDQS2, and the third internal data strobe signal iDQS3 may affect the reliability of the memory device 400. In particular, process, voltage, and temperature (PVT) variations affecting the memory device 400 may amplify the influence of reliability associated with these delay differences.

The host device 100 and the memory device 400 according to an embodiment of the present disclosure may perform the location-selective internal write leveling operation based on internal data strobe signals obtained at different locations. The host device 100 and the memory device 400 may select a location, at which the first write circuit WC1, the second write circuit WC2, and the third write circuit WC3 are capable of appropriately sampling the data signals DQ, as a final write leveling location. Accordingly, the time at which the memory device 400 samples the data signal DQ becomes more accurate, and the reliability of the memory device 400 is improved.

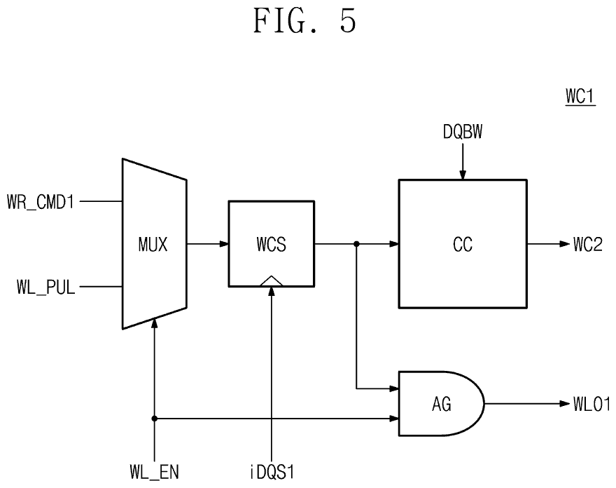

FIG. 5 illustrates the first write circuit WC1 according to an embodiment of the present disclosure. Referring to FIGS. 4 and 5, the first write circuit WC1 may include a multiplexer MUX, a write circuit sampler WCS, an AND gate AG, and a core circuit CC.

The multiplexer MUX may receive the first write command WR_CMD1 and the write leveling pulse signal WL_PUL. The multiplexer MUX may output one of the first write command WR_CMD1 and the write leveling pulse signal WL_PUL in response to a write leveling enable signal WL_EN. For example, when the write leveling enable signal WL_EN is in an active state, the multiplexer MUX may output the write leveling pulse signal WL_PUL. When the write leveling enable signal WL_EN is in an inactive state, the multiplexer MUX may output the first write command WR_CMD1. For example, the write leveling enable signal WL_EN may be received from the control logic CL and activated during both the external write leveling operation and the location-selective internal write leveling operation.

The write circuit sampler WCS may sample an output of the multiplexer MUX in synchronization with the first internal data strobe signal iDQS1. The sampled result from the write circuit sampler WCS is then transferred to the core circuit CC and the AND gate AG.

The AND gate AG may receive the output signal of the write circuit sampler WCS and the write leveling enable signal WL_EN. When both the output signal of the write circuit sampler WCS and the write leveling enable signal WL_EN are at the high level, the AND gate AG may output the first write leveling output signal WLO1 with the high level. When at least one of the output signal of the write circuit sampler WCS and the write leveling enable signal WL_EN is at the low level, the AND gate AG may output the first write leveling output signal WLO1 with the low level.

In other words, when the write leveling enable signal WL_EN is at the high level indicating that the write leveling operation is being performed, the AND gate AG may output the output signal of the write circuit sampler WCS as the first write leveling output signal WLO1. The output signal of the write circuit sampler WCS is, the result of sampling the write leveling pulse signal WL_PUL in synchronization with the first internal data strobe signal iDQS1.

The core circuit CC may receive the output signal of the write circuit sampler WCS and may receive the data signal DQ from the write data buffer DQBW. When the output of the write circuit sampler WCS is at the high level, the core circuit CC may perform a specific operation on the data signal DQ. In other words, in the write operation, when the first write command WR_CMD1 of the high level is received in synchronization with the first internal data strobe signal iDQS1, the core circuit CC may process the data signal DQ by performing a specific operation on the data signal DQ. The core circuit CC may output the processed data signal DQ to the second write circuit WC2.

A configuration of the second write circuit WC2 is similar to that of the first write circuit WC1, with a few differences: the second write circuit WC2 receives the second write command WR_CMD2 instead of the first write command WR_CMD1, it receives an internal write leveling signal (e.g., IWL_EN) activated in the location-selective internal write leveling operation, instead of the write leveling enable signal WL_EN, it receives the second internal data strobe signal iDQS2 instead of the first internal data strobe signal iDQS1, it outputs the second write leveling output signal WLO2 instead of the first write leveling output signal WLO1, it receives the data signal DQ from the first write circuit WC1 instead of the write data buffer DQBW, and the processed data signal DQ is output to the third write circuit WC3. Thus, additional description will be omitted to avoid redundancy.

Additionally, a configuration of the third write circuit WC3 is similar to that of the first write circuit WC1, with a few differences: the third write circuit WC3 receives the third write command WR_CMD3 instead of the first write command WR_CMD1, it receives an internal write leveling signal (e.g., IWL_EN) activated in the location-selective internal write leveling operation, instead of the write leveling enable signal WL_EN, it receives the third internal data strobe signal iDQS3 instead of the first internal data strobe signal iDQS1, it outputs the third write leveling output signal WLO3 instead of the first write leveling output signal WLO1, it receives the data signal DQ from the second write circuit WC2 instead of the write data buffer DQBW, and the processed data signal DQ is output to the bank BK. Thus, additional description will be omitted to avoid redundancy.

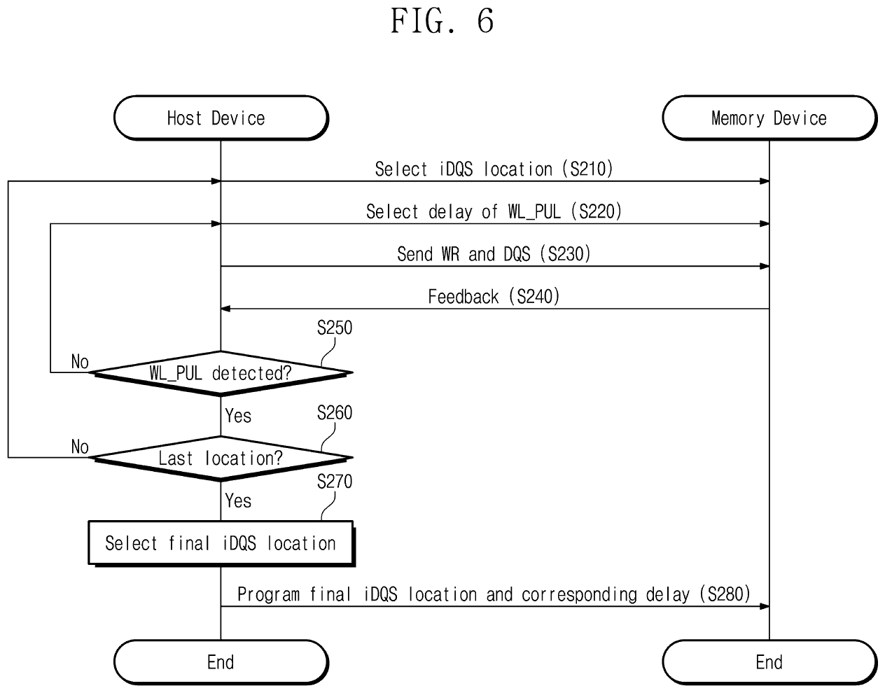

FIG. 6 illustrates an example of a method in which the memory device 400 of FIG. 4 performs the location-selective internal write leveling operation. Referring to FIGS. 1, 4, and 6, in operation S210, the host device 100 may select a location of the internal data strobe signal iDQS in the memory device 400. For example, the host device 100 may select one of the first internal data strobe signal iDQS1, the second internal data strobe signal iDQS2, and the third internal data strobe signal iDQS3 by programming a specific test mode register of the test mode register set TMRS of the control logic CL of the memory device 400.

In operation S220, the host device 100 may select a delay amount of the write leveling pulse signal WL_PUL. For example, the host device 100 may select the delay amount of the write leveling pulse signal WL_PUL, which corresponds to the selected internal data strobe signal iDQS, by programming the delay amount in the third mode register MR3 of the mode register set MRS of the control logic CL of the memory device 400.

In operation S230, the host device 100 may send the command and address CA indicating a write WR to the memory device 400 and may send the data strobe signal DQS. The host device 100 may send the data strobe signal DQS including the write preamble and at least one toggle to the memory device 400.

The command decoder CMDD of the memory device 400 may output the write leveling pulse signal WL_PUL in response to the command and address CA indicating the write WR. The write leveling pulse signal WL_PUL may have a delay amount corresponding to the information programmed in the third mode register MR3.

In operation S240, the memory device 400 may send feedback to the host device 100. In an embodiment, the first write circuit WC1, the second write circuit WC2, and the third write circuit WC3 may send the first write leveling output signal WLO1, the second write leveling output signal WLO2, and the third write leveling output signal WLO3, respectively, to the read circuit RC. The read circuit RC may provide a write leveling output signal corresponding to the selected internal data strobe signal iDQS from among the first write leveling output signal WLO1, the second write leveling output signal WLO2, and the third write leveling output signal WLO3 to the host device 100 through the data signal pads DQP as the data signal DQ.

As another example, a write circuit corresponding to the selected internal data strobe signal iDQS from among the first write circuit WC1, the second write circuit WC2, and the third write circuit WC3 may output the corresponding write leveling output signal to the read circuit RC. The read circuit RC may provide the received write leveling output signal to the host device 100 through the data signal pads DQP as the data signal DQ.

In operation S250, the host device 100 may determine whether the write leveling pulse signal WL_PUL is detected. For example, when the feedback provided from the memory device 400 is a signal of the high level (or low level), the host device 100 may determine that the write leveling pulse signal WL_PUL is detected. When the feedback provided from the memory device 400 is a signal of the low level (or high level), the host device 100 may determine that the write leveling pulse signal WL_PUL is not detected.

When the write leveling pulse signal WL_PUL is not detected, the host device 100 may again select the delay amount of the write leveling pulse signal WL_PUL. In other words, operation S220 is performed again. Afterwards, the host device 100 and the memory device 400 may again perform operation S230, operation S240, and operation S250. In other words, until the write leveling pulse signal WL_PUL is detected, the host device 100 and the memory device 400 may sweep the delay amount of the write leveling pulse signal WL_PUL.

When the write leveling pulse signal WL_PUL is detected, the host device 100 may store the delay amount of the write leveling pulse signal WL_PUL corresponding to the selected internal data strobe signal iDQS. This delay amount represent the specific point in time when the write leveling pulse signal WL_PUL is detected. Afterwards, operation S260 is performed.

In operation S260, the host device 100 may determine whether the selected location is the last location. This involves assessing all the targets of the location-selective internal write leveling operation, in other words, the first internal data strobe signal iDQS1, the second internal data strobe signal iDQS2, and the third internal data strobe signal iDQS3, the host device 100, to determine if the delay amount of the write leveling pulse signal WL_PUL has been detected for each.

When the selected location is not the last location, the host device 100 may select a next internal data strobe signal iDQS. In other words, operation S210 is performed again. Afterwards, the host device 100 and the memory device 400 may perform operation S220, operation S230, operation S240, operation S250, and operation S260. In other words, until the delay amount of the write leveling pulse signal WL_PUL is detected for each internal data strobe signal, the host device 100 and the memory device 400 may sequentially select the internal data strobe signals and may detect the delay amount of the corresponding write leveling pulse signal WL_PUL.

When the selected location is the last location, in operation S270, the host device 100 may select a final internal data strobe signal (iDQS) location. For example, based on the internal data strobe signals and corresponding delay amounts of the write leveling pulse signals, the host device 100 may select a delay amount for the write leveling pulse signal WL_PUL that can appropriately sample the data signals DQ in the first write circuit WC1, the second write circuit WC2, and the third write circuit WC3. The host device 100 may select an internal data strobe signal (iDQS) location corresponding to the selected delay amount of the write leveling pulse signal WL_PUL as the final internal data strobe signal (iDQS) location.

In operation S280, the host device 100 may program the final internal data strobe signal (iDQS) location and the corresponding delay amount in the memory device 400. For example, the host device 100 may program information of the final internal data strobe signal (iDQS) location in a specific test mode register of the test mode register set TMRS of the control logic CL of the memory device 400. For example, the host device 100 programs information of the second internal data strobe signal iDQS2 in the test mode register.

The host device 100 may program the delay amount of the write leveling pulse signal WL_PUL corresponding to the second internal data strobe signal iDQS2 in the third mode register MR3 of the mode register set MRS of the control logic CL of the memory device 400. Afterwards, the location-selective internal write leveling operation may be exited.

In an embodiment, in the write operation, the first write command WR_CMD1, the second write command WR_CMD2, and the third write command WR_CMD3 may be activated in synchronization with the clock signal CK with a specific time difference (e.g., a CWL difference). The first write command WR_CMD1, the second write command WR_CMD2, and the third write command WR_CMD3 may be delayed with respect to the clock signal CK by the delay amount programmed in the third mode register MR3, and then activated.

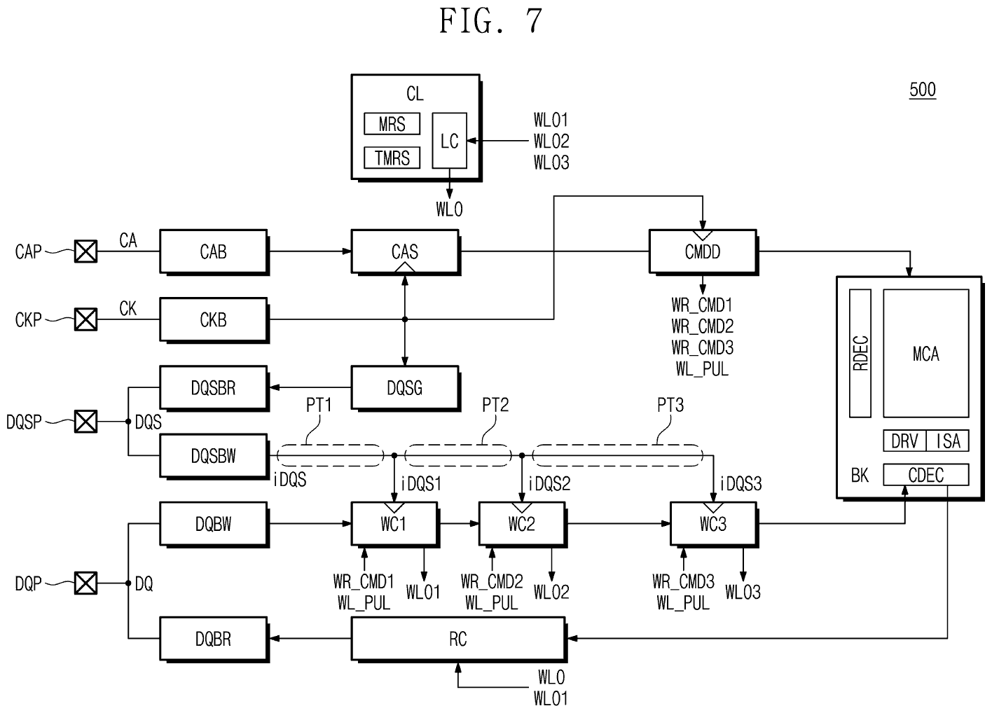

FIG. 7 illustrates a memory device 500 according to an embodiment of the present disclosure. Referring to FIGS. 1 and 7, the memory device 500 may include the command and address pad CAP, the command and address buffer CAB, the clock signal pad CKP, the clock buffer CKB, the data strobe signal pad DQSP, the write data strobe buffer DQSBW, the read data strobe buffer DQSBR, the data signal pad DQP, the write data buffer DQBW, the read data buffer DQBR, the command and address sampler CAS, the command decoder CMDD, the data strobe signal generator DQSG, the first write circuit WC1, the second write circuit WC2, the third write circuit WC3, the first path PT1, the second path PT2, and the third path PT3, through which the internal data strobe signal iDQS is transferred, the bank BK, the read circuit RC, and the control logic CL. The bank BK may include the memory cell array MCA, the row decoder RDEC, the write driver DRV, the sense amplifier ISA, and the column decoder CDEC.

Components of the memory device 500 are the same as the components of the memory device 400 described with reference to FIGS. 4 and 6 except for the read circuit RC and the control logic CL, and an operation of the memory device 500 is similar to the operation of the memory device 400. Thus, additional description will be omitted to avoid redundancy.

The control logic CL may include the mode register set MRS, the test mode register set TMRS, and a logic circuit LC. Configurations and operations of the mode register set MRS and the test mode register set TMRS are similar to the configurations and operations of the mode register set MRS and the test mode register set TMRS described with reference to FIGS. 4 and 6, except that the test mode register set TMRS is not used to select internal data strobe signal locations. Thus, additional description will be omitted to avoid redundancy.

The logic circuit LC may receive the first write leveling output signal WLO1 from the first write circuit WC1, the second write leveling output signal WLO2 from the second write circuit WC2, and the third write leveling output signal WLO3 from the third write circuit WC3.

The logic circuit LC may perform a logical operation on the first write leveling output signal WLO1, the second write leveling output signal WLO2, and the third write leveling output signal WLO3. For example, the logic circuit LC may perform an OR operation or an AND operation on the first write leveling output signal WLO1, the second write leveling output signal WLO2, and the third write leveling output signal WLO3.

The number and types of logical operations that the logic circuit LC can perform are not limited. For example, the logic circuit LC may be configured to perform two or more of various logical operations including OR, AND, exclusive OR, exclusive AND, NOR, NAND, exclusive NOR, and exclusive NAND operations, step by step at one or more stages.

The logic circuit LC may output a result of the logical operation performed on the first write leveling output signal WLO1, the second write leveling output signal WLO2, and the third write leveling output signal WLO3 as a write leveling output signal WLO.

In the external write leveling operation, the read circuit RC may receive the first write leveling output signal WLO1 from the first write circuit WC1. In the location-selective internal write leveling operation, the read circuit RC may receive the write leveling output signal WLO from the logic circuit LC of the control logic CL. The read circuit RC may provide the first write leveling output signal WLO1 or the write leveling output signal WLO to the host device 100 through the data signal pad DQP as a feedback.

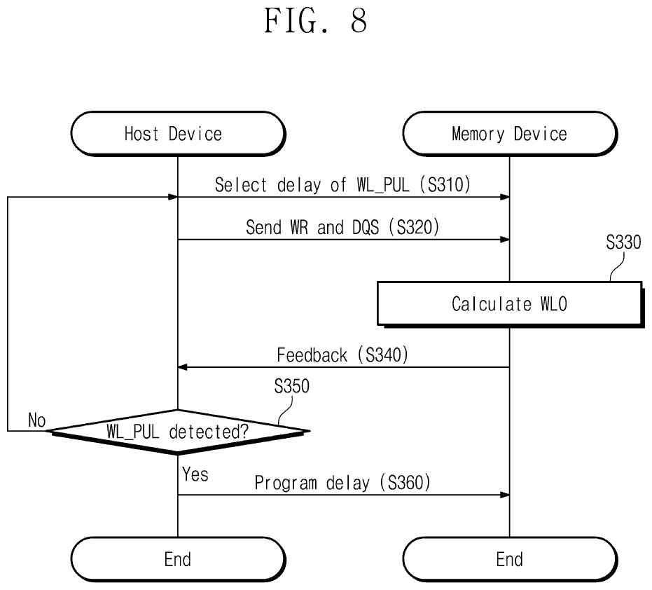

FIG. 8 illustrates an example of a method in which the memory device 500 of FIG. 7 performs the location-selective internal write leveling operation. Referring to FIGS. 1, 7, and 8, in operation S310, the host device 100 may select a delay amount of the write leveling pulse signal WL_PUL. For example, the host device 100 may select the delay amount of the write leveling pulse signal WL_PUL corresponding to the selected internal data strobe signal iDQS by programming the delay amount in the third mode register MR3 of the mode register set MRS of the control logic CL of the memory device 500.

In operation S320, the host device 100 may send the command and address CA indicating the write WR to the memory device 500 and may send the data strobe signal DQS. The host device 100 may send the data strobe signal DQS including the write preamble and at least one toggle to the memory device 500.

The command decoder CMDD of the memory device 500 may output the write leveling pulse signal WL_PUL in response to the command and address CA indicating the write WR. The write leveling pulse signal WL_PUL may have a delay amount corresponding to the information programmed in the third mode register MR3.

In operation S330, the memory device 500 may calculate the write leveling output signal WLO. For example, the logic circuit LC of the control logic CL of the memory device 500 may calculate the write leveling output signal WLO by performing a logical operation on the first write leveling output signal WLO1, the second write leveling output signal WLO2, and the third write leveling output signal WLO3.

In operation S340, the memory device 500 may send feedback to the host device 100. In an embodiment, the logic circuit LC of the control logic CL of the memory device 500 may send the write leveling output signal WLO to the read circuit RC. The read circuit RC may provide the write leveling output signal WLO to the host device 100 through the data signal pads DQP as the data signal DQ.

In operation S350, the host device 100 may determine whether the write leveling pulse signal WL_PUL is detected. For example, when the feedback provided from the memory device 500 is a signal of the high level (or low level), the host device 100 may determine that the write leveling pulse signal WL_PUL is detected. When the feedback provided from the memory device 500 is a signal of the low level (or high level), the host device 100 may determine that the write leveling pulse signal WL_PUL is not detected.

When the write leveling pulse signal WL_PUL is not detected, the host device 100 may reselect the delay amount of the write leveling pulse signal WL_PUL. In other words, operation S310 is performed again. Afterwards, the host device 100 and the memory device 500 may again perform operation S320, operation S330, and operation S340. In other words, until the write leveling pulse signal WL_PUL is detected, the host device 100 and the memory device 500 may sweep the delay amount of the write leveling pulse signal WL_PUL.

When the write leveling pulse signal WL_PUL is detected, the host device 100 may program the delay amount in the memory device 500. For example, the host device 100 may program the delay amount of the detected write leveling pulse signal WL_PUL in the third mode register MR3 of the mode register set MRS of the control logic CL of the memory device 500. Afterwards, the location-selective internal write leveling operation may be exited.

In an embodiment, in the write operation, the first write command WR_CMD1, the second write command WR_CMD2, and the third write command WR_CMD3 may be activated in synchronization with the clock signal CK with a specific time difference (e.g., a CWL difference). The first write command WR_CMD1, the second write command WR_CMD2, and the third write command WR_CMD3 may be delayed with respect to the clock signal CK by the delay amount programmed in the third mode register MR3. Once this delay is applied, these commands (WR_CMD1, WR_CMD2 and WR_CMD3) may be activated.

As described above, the host device 100 and the memory device 500 may skip testing for a plurality of internal data strobe signal locations. Instead, they may select the delay amount of the first write command WR_CMD1, the second write command WR_CMD2, and the third write command WR_CMD3 based on a result obtained by the logic circuit LC performing a logical operation on the plurality of internal data strobe signal locations. Accordingly, a time of the location-selective internal write leveling operation may be shortened.

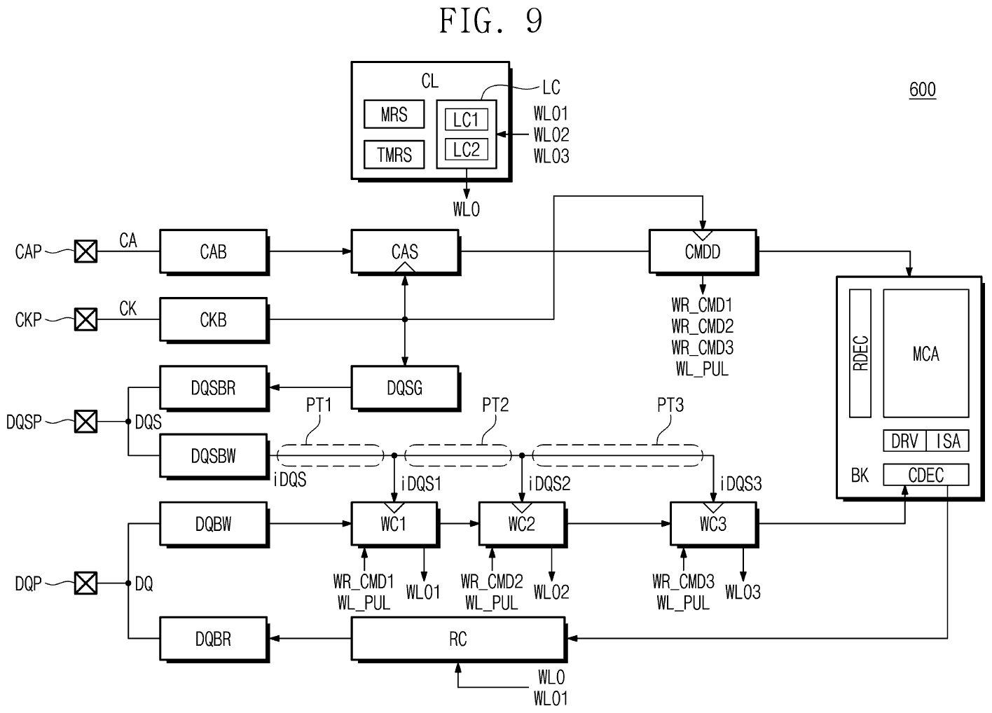

FIG. 9 illustrates a memory device 600 according to an embodiment of the present disclosure. Referring to FIGS. 1 and 9, the memory device 600 may include the command and address pad CAP, the command and address buffer CAB, the clock signal pad CKP, the clock buffer CKB, the data strobe signal pad DQSP, the write data strobe buffer DQSBW, the read data strobe buffer DQSBR, the data signal pad DQP, the write data buffer DQBW, the read data buffer DQBR, the command and address sampler CAS, the command decoder CMDD, the data strobe signal generator DQSG, the first write circuit WC1, the second write circuit WC2, the third write circuit WC3, the first path PT1, the second path PT2, and the third path PT3, through which the internal data strobe signal iDQS is transferred, the bank BK, the read circuit RC, and the control logic CL. The bank BK may include the memory cell array MCA, the row decoder RDEC, the write driver DRV, the sense amplifier ISA, and the column decoder CDEC.

Components of the memory device 600 are similar to the components of the memory device 400 described with reference to FIGS. 4 and 6 except for the read circuit RC and the control logic CL, and an operation of the memory device 600 is similar to the operation of the memory device 400. Thus, additional description will be omitted to avoid redundancy.

The control logic CL may include the mode register set MRS, the test mode register set TMRS, and the logic circuit LC. Configurations and operations of the mode register set MRS and the test mode register set TMRS are similar to the configurations and operations of the mode register set MRS and the test mode register set TMRS described with reference to FIGS. 4 and 6, except that the test mode register set TMRS is not used to select internal data strobe signal locations and the test mode register set TMRS is used to select one of a first logic circuit LC1 and a second logic circuit LC2. Thus, additional description will be omitted to avoid redundancy.

The logic circuit LC may receive the first write leveling output signal WLO1 from the first write circuit WC1, the second write leveling output signal WLO2 from the second write circuit WC2, and the third write leveling output signal WLO3 from the third write circuit WC3.

The logic circuit LC may perform a logical operation on the first write leveling output signal WLO1, the second write leveling output signal WLO2, and the third write leveling output signal WLO3. The logic circuit LC may include the first logic circuit LC1 and the second logic circuit LC2. For example, the first logic circuit LC1 may perform one of an OR operation and an AND operation on the first write leveling output signal WLO1, the second write leveling output signal WLO2, and the third write leveling output signal WLO3. The second logic circuit LC2 may perform the other of the OR operation and the AND operation on the first write leveling output signal WLO1, the second write leveling output signal WLO2, and the third write leveling output signal WLO3.

In an embodiment, the number and types of logical operations that the first logic circuit LC1 and the second logic circuit LC2 perform are not limited. For example, the first logic circuit LC1 and the second logic circuit LC2 may be configured to perform two or more of various logical operations including OR, AND, exclusive OR, exclusive AND, NOR, NAND, exclusive NOR, and exclusive NAND operations, step by step at one or more stages.

A logic circuit selected from the first logic circuit LC1 and the second logic circuit LC2 may output a result of the logical operation on the first write leveling output signal WLO1, the second write leveling output signal WLO2, and the third write leveling output signal WLO3 as the write leveling output signal WLO. For example, one of the first logic circuit LC1 and the second logic circuit LC2 may be selected by using the test mode register set TMRS.

In the external write leveling operation, the read circuit RC may receive the first write leveling output signal WLO1 from the first write circuit WC1. In the location-selective internal write leveling operation, the read circuit RC may receive the write leveling output signal WLO from the logic circuit LC of the control logic CL. The read circuit RC may provide the first write leveling output signal WLO1 or the write leveling output signal WLO to the host device 100 through the data signal pad DQP as feedback.

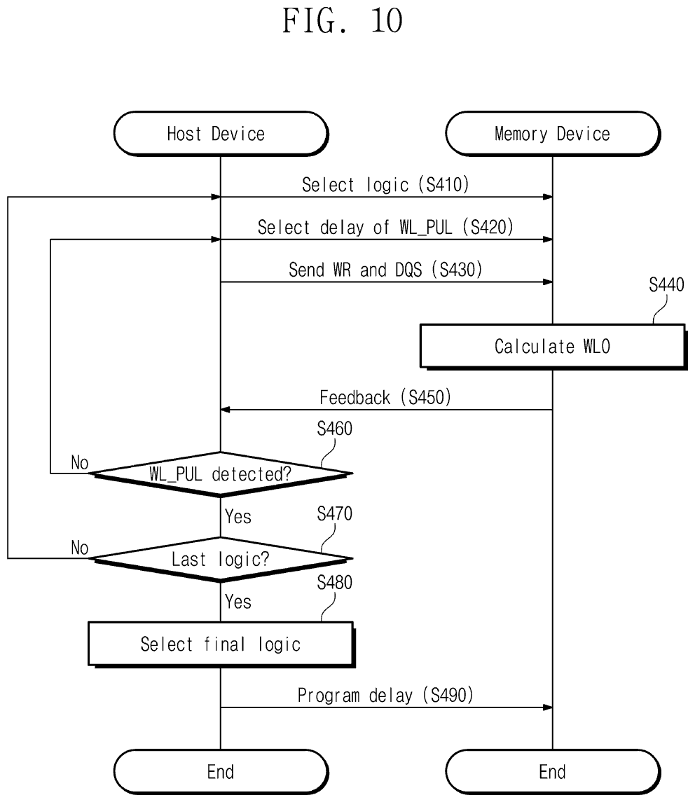

FIG. 10 illustrates an example of a method in which the memory device 600 of FIG. 9 performs the location-selective internal write leveling operation. Referring to FIGS. 1, 9, and 10, in operation S410, the host device 100 may select logic in the memory device 600. For example, the host device 100 may select one of the first logic circuit LC1 and the second logic circuit LC2 by programming a specific test mode register of the test mode register set TMRS of the control logic CL of the memory device 600.

In operation S420, the host device 100 may select a delay amount of the write leveling pulse signal WL_PUL. For example, the host device 100 may select the delay amount of the write leveling pulse signal WL_PUL that corresponds to the selected internal data strobe signal iDQS by programming the delay amount in the third mode register MR3 of the mode register set MRS of the control logic CL of the memory device 600.

In operation S430, the host device 100 may send the command and address CA indicating the write WR to the memory device 600 and may send the data strobe signal DQS. The host device 100 may send the data strobe signal DQS including the write preamble and at least one toggle to the memory device 600.

The command decoder CMDD of the memory device 600 may output the write leveling pulse signal WL_PUL in response to the command and address CA indicating the write WR. The write leveling pulse signal WL_PUL may have a delay amount corresponding to the information programmed in the third mode register MR3.

In operation S440, the memory device 600 may calculate the write leveling output signal WLO. For example, a logic circuit selected from the first logic circuit LC1 and the second logic circuit LC2 of the logic circuit LC of the control logic CL of the memory device 600 may calculate the write leveling output signal WLO by performing a logical operation on the first write leveling output signal WLO1, the second write leveling output signal WLO2, and the third write leveling output signal WLO3.

In operation S450, the memory device 600 may send feedback to the host device 100. In an embodiment, a logic circuit selected from the first logic circuit LC1 and the second logic circuit LC2 of the logic circuit LC of the control logic CL of the memory device 600 may send the write leveling output signal WLO to the read circuit RC. The read circuit RC may provide the write leveling output signal WLO to the host device 100 through the data signal pads DQP as the data signal DQ.

In operation S460, the host device 100 may determine whether the write leveling pulse signal WL_PUL is detected. For example, when the feedback provided from the memory device 600 is a signal of the high level (or low level), the host device 100 may determine that the write leveling pulse signal WL_PUL is detected. When the feedback provided from the memory device 600 is a signal of the low level (or high level), the host device 100 may determine that the write leveling pulse signal WL_PUL is not detected.

When the write leveling pulse signal WL_PUL is not detected, the host device 100 may again select the delay amount of the write leveling pulse signal WL_PUL. In other words, operation S420 may be performed again. Afterwards, the host device 100 and the memory device 600 may again perform operation S430, operation S440, operation S450, and operation S460. In other words, until the write leveling pulse signal WL_PUL is detected, the host device 100 and the memory device 600 may sweep the delay amount of the write leveling pulse signal WL_PUL.

When the write leveling pulse signal WL_PUL is detected, the host device 100 may record the delay amount associated with the write leveling pulse signal WL_PUL for the selected logic circuit. This recorded delay corresponds to the specific point in time when the write leveling pulse signal WL_PUL is detected. Afterwards, operation S470 is performed.

In operation S470, the host device 100 may determine whether the selected logic circuit is the last logic circuit. For example, the host device 100 may determine whether the delay amount of the write leveling pulse signal WL_PUL for each of the first logic circuit LC1 and the second logic circuit LC2 is detected.

When the selected logic circuit is not the last logic circuit, the host device 100 may select a next logic circuit. In other words, operation S410 may be performed again. Afterwards, the host device 100 and the memory device 600 may perform operation S420, operation S430, operation S440, operation S450, operation S460, and operation S470. In other words, until the delay amount of the write leveling pulse signal WL_PUL is detected for each of the first logic circuit LC1 and the second logic circuit LC2, the host device 100 and the memory device 600 may sequentially select the first logic circuit LC1 and the second logic circuit LC2 to detect the corresponding delay amount of the write leveling pulse signal WL_PUL for each of the first and second logic circuits LC1 and LC2.

When the selected logic circuit is the last logic circuit, in operation S480, the host device 100 may select a final logic circuit. For example, based on the first logic circuit LC1, the second logic circuit LC2, and delay amounts of their corresponding write leveling pulse signals, the host device 100 may select the delay amount of the write leveling pulse signal WL_PUL that can appropriately sample the data signals DQ in the first write circuit WC1, the second write circuit WC2, and the third write circuit WC3. The host device 100 may select an internal data strobe signal (iDQS) location corresponding to the selected delay amount of the write leveling pulse signal WL_PUL as the final internal data strobe signal (iDQS) location.

In operation S490, the host device 100 may program the final logic circuit and the corresponding delay amount in the memory device 600. For example, the host device 100 may program information of the final logic circuit in a specific test mode register of the test mode register set TMRS of the control logic CL of the memory device 600.

The host device 100 may program the delay amount of the write leveling pulse signal WL_PUL corresponding to the final logic circuit in the third mode register MR3 of the mode register set MRS of the control logic CL of the memory device 600. Afterwards, the location-selective internal write leveling operation may be exited.

In an embodiment, in the write operation, the first write command WR_CMD1, the second write command WR_CMD2, and the third write command WR_CMD3 may be activated in synchronization with the clock signal CK with a given time difference (e.g., a CWL difference). The first write command WR_CMD1, the second write command WR_CMD2, and the third write command WR_CMD3 may be delayed with respect to the clock signal CK by the delay amount programmed in the third mode register MR3. After this delay, these commands (WR_CMD1, WR_CMD2 and WR_CMD3) may be activated.

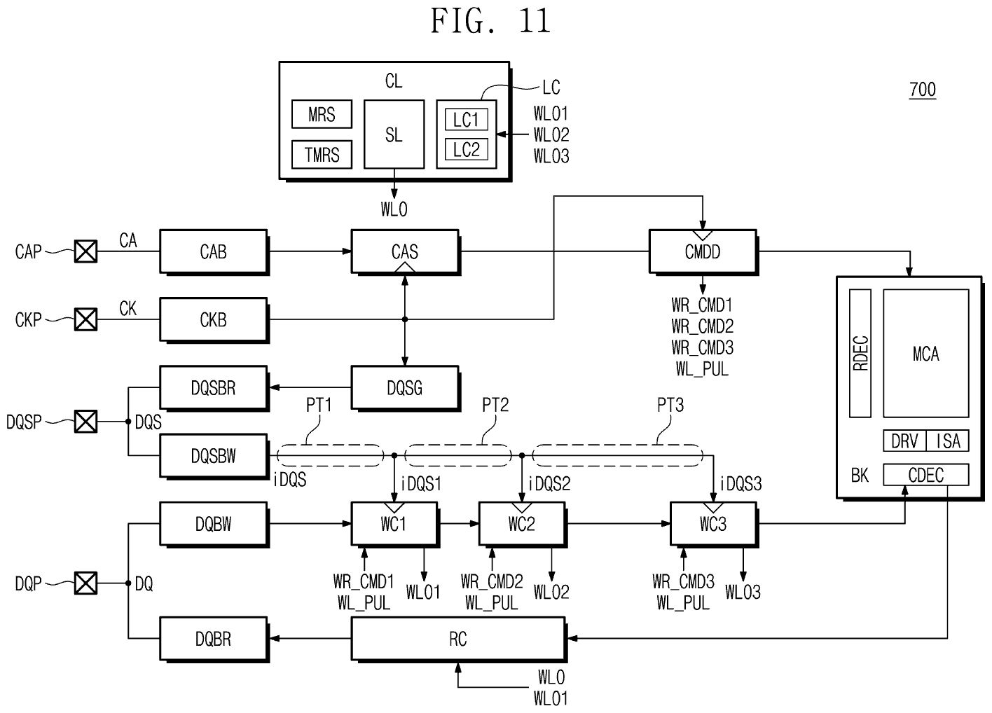

FIG. 11 illustrates a memory device 700 according to an embodiment of the present disclosure. Referring to FIGS. 1 and 11, the memory device 700 may include the command and address pad CAP, the command and address buffer CAB, the clock signal pad CKP, the clock buffer CKB, the data strobe signal pad DQSP, the write data strobe buffer DQSBW, the read data strobe buffer DQSBR, the data signal pad DQP, the write data buffer DQBW, the read data buffer DQBR, the command and address sampler CAS, the command decoder CMDD, the data strobe signal generator DQSG, the first write circuit WC1, the second write circuit WC2, the third write circuit WC3, the first path PT1, the second path PT2, and the third path PT3, through which the internal data strobe signal iDQS is transferred, the bank BK, the read circuit RC, and the control logic CL. The bank BK may include the memory cell array MCA, the row decoder RDEC, the write driver DRV, the sense amplifier ISA, and the column decoder CDEC.

Components of the memory device 700 are similar to the components of the memory device 400 described with reference to FIGS. 4 and 6, except for the read circuit RC and the control logic CL, and an operation of the memory device 700 is similar to the operation of the memory device 400. Thus, additional description will be omitted to avoid redundancy.

The control logic CL may include the mode register set MRS, the test mode register set TMRS, and the logic circuit LC. Configurations and operations of the mode register set MRS and the test mode register set TMRS are similar to the configurations and operations of the mode register set MRS and the test mode register set TMRS described with reference to FIGS. 4 and 6, except that the test mode register set TMRS is not used to select internal data strobe signal locations. Thus, additional description will be omitted to avoid redundancy.

The logic circuit LC may receive the first write leveling output signal WLO1 from the first write circuit WC1, the second write leveling output signal WLO2 from the second write circuit WC2, and the third write leveling output signal WLO3 from the third write circuit WC3.

The logic circuit LC may perform a logical operation on the first write leveling output signal WLO1, the second write leveling output signal WLO2, and the third write leveling output signal WLO3. The logic circuit LC may include the first logic circuit LC1 and the second logic circuit LC2. For example, the first logic circuit LC1 may perform one of an OR operation and an AND operation on the first write leveling output signal WLO1, the second write leveling output signal WLO2, and the third write leveling output signal WLO3. The second logic circuit LC2 may perform the other of the OR operation and the AND operation on the first write leveling output signal WLO1, the second write leveling output signal WLO2, and the third write leveling output signal WLO3.

In an embodiment, the number and types of logical operations that the first logic circuit LC1 and the second logic circuit LC2 perform are not limited. For example, the first logic circuit LC1 and the second logic circuit LC2 may be configured to perform two or more of various logical operations including OR, AND, exclusive OR, exclusive AND, NOR, NAND, exclusive NOR, and exclusive NAND operations, step by step at one or more stages.

The control logic CL may further include selection logic SL. The first logic circuit LC1 and the second logic circuit LC2 may provide the selection logic SL with results of the logical operations performed on the first write leveling output signal WLO1, the second write leveling output signal WLO2, and the third write leveling output signal WLO3. The selection logic SL may output, as the write leveling output signal WLO, one of the results of the logical operations performed on the first write leveling output signal WLO1, the second write leveling output signal WLO2, and the third write leveling output signal WLO3.

For example, the selection logic SL may generate the write leveling output signal WLO based on a first timing, when the output of the first logic circuit LC1 is set to the high level, and a second timing, when the output of the second logic circuit LC2 is set to the high level. If the time difference between the first timing and the second timing is less than a threshold value, the selection logic SL may output one (e.g., an AND output) of the output of the first logic circuit LC1 and the output of the second logic circuit LC2 as the write leveling output signal WLO. If the time difference between the first timing and the second timing is greater than or equal to the threshold value, the selection logic SL may output a signal, which is obtained by delaying one (e.g., an OR output) of the output of the first logic circuit LC1 and the output of the second logic circuit LC2 by a specified offset and output is as the write leveling output signal WLO.

In the external write leveling operation, the read circuit RC may receive the first write leveling output signal WLO1 from the first write circuit WC1. In the location-selective internal write leveling operation, the read circuit RC may receive the write leveling output signal WLO from the logic circuit LC of the control logic CL. The read circuit RC may provide the first write leveling output signal WLO1 or the write leveling output signal WLO to the host device 100 through the data signal pad DQP as feedback.

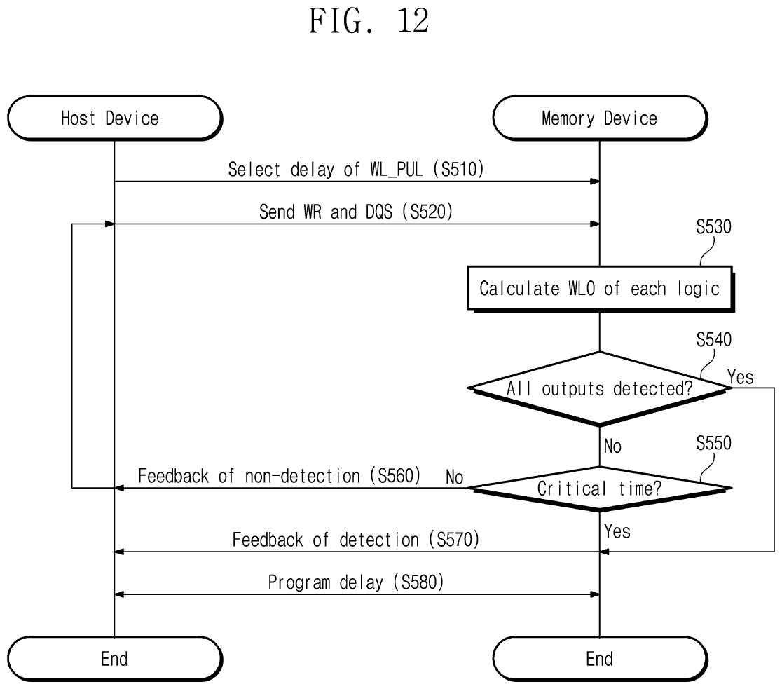

FIG. 12 illustrates an example of a method in which the memory device 700 of FIG. 11 performs the location-selective internal write leveling operation. Referring to FIGS. 1, 11, and 12, in operation S510, the host device 100 may select a delay amount of the write leveling pulse signal WL_PUL. For example, the host device 100 may select the delay amount of the write leveling pulse signal WL_PUL corresponding to a selected internal data strobe signal iDQS by programming the delay amount in the third mode register MR3 of the mode register set MRS of the control logic CL of the memory device 700.

In operation S520, the host device 100 may send the command and address CA indicating the write WR to the memory device 700 and may send the data strobe signal DQS. The host device 100 may send the data strobe signal DQS including the write preamble and at least one toggle to the memory device 700.

The command decoder CMDD of the memory device 700 may output the write leveling pulse signal WL_PUL in response to the command and address CA indicating the write WR. The write leveling pulse signal WL_PUL may have a delay amount corresponding to the information programmed in the third mode register MR3.

In operation S530, the memory device 700 may calculate the write leveling output signal WLO. For example, each of the first logic circuit LC1 and the second logic circuit LC2 of the logic circuit LC of the control logic CL of the memory device 700 may perform a logical operation on the first write leveling output signal WLO1, the second write leveling output signal WLO2, and the third write leveling output signal WLO3.

In operation S540, the memory device 700 may determine whether all outputs are detected. For example, the selection logic SL of the control logic CL of the memory device 700 may determine whether both the output of the first logic circuit LC1 and the output of the second logic circuit LC2 are at the high level.

When all the outputs are not detected, in other words, when at least one of the output of the first logic circuit LC1 and the output of the second logic circuit LC2 is not at the high level, in operation S550, the selection logic SL may determine whether a critical time passes. For example, after at least one of the output of the first logic circuit LC1 and the output of the second logic circuit LC2 is set to the high level, the selection logic SL may determine whether the critical time passes.

When at least one of the output of the first logic circuit LC1 and the output of the second logic circuit LC2 is not at the high level (No in operation S540) and when the critical time does not pass from a point in time when at least one of the output of the first logic circuit LC1 and the output of the second logic circuit LC2 is set to the high level (No in operation S550), the memory device 700 may provide a non-detection feedback to the host device 100. For example, the selection logic SL may provide the write leveling output signal WLO of the low level to the read circuit RC, and the read circuit RC may provide the write leveling output signal WLO of the low level to the host device 100. In response to the non-detection feedback, in operation S510, the host device 100 may again select a delay amount of the write leveling pulse signal WL_PUL. Afterwards, the host device 100 and the memory device 700 may again perform operation S520, operation S530, operation S540, operation S540, and operation S550. In other words, until the write leveling pulse signal WL_PUL is detected, the host device 100 and the memory device 700 may sweep the delay amount of the write leveling pulse signal WL_PUL.

When both the output of the first logic circuit LC1 and the output of the second logic circuit LC2 are at the high level (Yes in operation S540), the memory device 700 may provide a detection feedback to the host device 100; alternatively, when at least one of the output of the first logic circuit LC1 and the output of the second logic circuit LC2 is not at the high level (No in operation S540) and when the critical time passes from a point in time when at least one of the output of the first logic circuit LC1 and the output of the second logic circuit LC2 is set to the high level (Yes in operation S550), the memory device 700 may provide a detection feedback to the host device 100. For example, the selection logic SL may provide the write leveling output signal WLO of the high level to the read circuit RC, and the read circuit RC may provide the write leveling output signal WLO of the high level to the host device 100.

In operation S580, the host device 100 may program the delay amount in the memory device 700. For example, the host device 100 may program the delay amount of the write leveling pulse signal WL_PUL in the third mode register MR3 of the mode register set MRS of the control logic CL of the memory device 700. Afterwards, the location-selective internal write leveling operation may be exited.

In an embodiment, in the write operation, the first write command WR_CMD1, the second write command WR_CMD2, and the third write command WR_CMD3 may be activated in synchronization with the clock signal CK with a given time difference (e.g., a CWL difference). The first write command WR_CMD1, the second write command WR_CMD2, and the third write command WR_CMD3 may be delayed with respect to the clock signal CK by the delay amount programmed in the third mode register MR3 and then be activated.

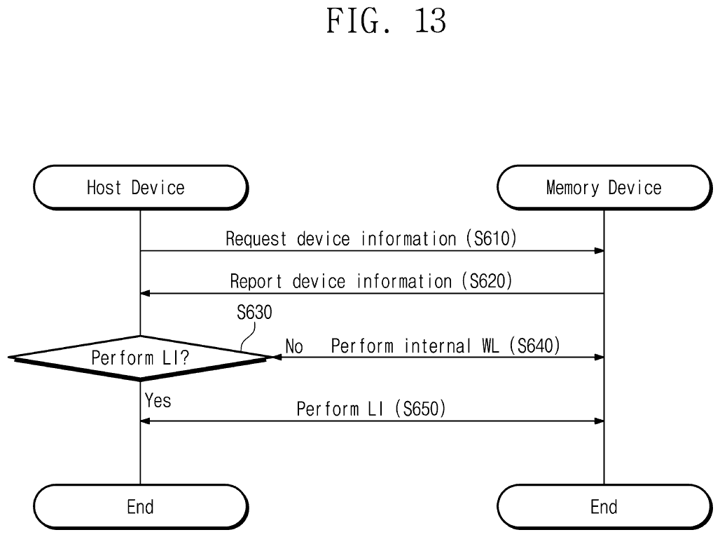

FIG. 13 illustrates an example of an operating method of the host device 100 and the memory device 210 or 220. Referring to FIGS. 1 and 13, in operation S610, the host device 100 may request device information from the memory device 210 or 220. For example, the host device 100 may request the device information to the memory device 210 or 220 in the process of initializing the memory device 210 or 220. For example, the device information may be information associated with the location-selective internal write leveling operation.

In operation S620, the memory device 210 or 220 may report the device information to the host device 100. For example, the device information may include information about whether the memory device 210 or 220 supports the location-selective internal write leveling operation, information about selectable locations as described with reference to FIGS. 4 and 6, information about a type of an operation of the logic circuit LC as described with reference to FIGS. 7 and 8, information about the number or types of logic circuits as described with reference to FIGS. 9 and 10, and information about the number and types of logic circuits and an algorithm of the selection logic SL as described with reference to FIGS. 11 and 12.

In operation S630, the host device 100 may determine whether to perform a location-selective internal write leveling operation LI. When it is determined that there is no need to perform the location-selective internal write leveling operation LI, in operation S640, the host device 100 may perform the internal write leveling operation with the memory device 210 or 220. When it is determined that there is a need to perform the location-selective internal write leveling operation LI, in operation S650, the host device 100 may perform the location-selective internal write leveling operation LI with the memory device 210 or 220.

According to embodiments of the present disclosure, internal data strobe signals are obtained from two or more locations, and a write leveling operation is performed based on these signals. This approach enhances the reliability of the memory device by ensuring communication signals are obtained at more accurate timings. Additionally, this method provides an improved operating procedure for the memory device, and includes a memory module incorporating the memory device.

Although the present disclosure has been described with reference to specific embodiments, those of ordinary skill in the art will recognize that various changes and modifications can be made without departing from the spirit and scope of the present disclosure as set forth in the following claims.

What is claimed is:

1. A memory device comprising:
a memory cell array including a plurality of memory cells;
a command decoder configured to receive a write command signal from a host device in synchronization with a clock signal received from the host device and to generate a write leveling pulse signal in response to the write command signal and in synchronization with the clock signal in a write leveling operation;
a data strobe signal path configured to transfer a data strobe signal received from the host device;
a first write circuit configured to receive a first data strobe signal at a first location on the data strobe signal path, to first sample the write leveling pulse signal in synchronization with the first data strobe signal in the write leveling operation, and to output a first write leveling signal based on the first sampling; and
a second write circuit configured to receive a second data strobe signal at a second location on the data strobe signal path, to second sample the write leveling pulse signal in synchronization with the second data strobe signal in the write leveling operation, and to output a second write leveling signal based on the second sampling,
wherein, in the write leveling operation, the memory device is configured to generate a feedback signal to be sent to the host device based on the first write leveling signal and the second write leveling signal.

2. The memory device of claim 1, wherein the memory device is configured to select the first write leveling signal or the second write leveling signal to be output to the host device as the feedback signal.

3. The memory device of claim 2, wherein the memory device is configured to select the first write leveling signal or the second write leveling signal based on a request of the host device.

4. The memory device of claim 3, further comprising:
a test mode register set (TMRS),
wherein the memory device is configured to select the first write leveling signal or the second write leveling signal based on information programmed in the TMRS.

5. The memory device of claim 1, wherein, in a write operation, the command decoder is further configured to generate a first write command signal and a second write command signal in response to the write command signal, and
wherein, in the write operation, the first write circuit and the second write circuit are further configured to receive the first write command signal and the second write command signal, respectively.

6. The memory device of claim 5, wherein, in the write operation, the first write circuit is configured to sample the first write command signal in synchronization with the first data strobe signal, and
wherein, in the write operation, the second write circuit is further configured to sample the second write command signal in synchronization with the second data strobe signal.

7. The memory device of claim 5, wherein the command decoder is configured to output the first write command signal and the second write command signal with a time difference corresponding to an offset time.

8. The memory device of claim 1, wherein a toggle timing of the first data strobe signal is different from a toggle timing of the second data strobe signal.

9. The memory device of claim 1, further comprising:
a logic circuit configured to receive the first write leveling output signal and the second write leveling output signal, to perform a logical operation on the first write leveling output signal and the second write leveling output signal, wherein a result of the logical operation is the feedback signal.

10. The memory device of claim 9, wherein the logic circuit is configured to perform an OR operation or an AND operation.

11. The memory device of claim 1, further comprising:
a first logic circuit configured to receive the first write leveling output signal and the second write leveling output signal and to perform a first logical operation on the first write leveling output signal and the second write leveling output signal; and
a second logic circuit configured to receive the first write leveling output signal and the second write leveling output signal and to perform a second logical operation on the first write leveling output signal and the second write leveling output signal.

12. The memory device of claim 11, wherein a first output of the first logic circuit or a second output of the second logic circuit is the feedback signal.

13. The memory device of claim 12, wherein the memory device is configured to select the first output or the second output based on a request of the host device.

14. The memory device of claim 11, wherein the memory device is configured to provide the host device with information about the number of logic circuits used to generate the feedback signal.

15. The memory device of claim 11, further comprising:
a third logic circuit configured to receive a first output of the first logic circuit and a second output of the second logic circuit and to select a delay amount of the write leveling pulse signal based on the first output and the second output.

16. The memory device of claim 15, wherein, in a write operation, the command decoder is further configured to generate the first write command signal and the second write command signal in response to the write command signal, and
wherein, in the write operation, the first write circuit and the second write circuit are further configured to receive the first write command signal and the second write command signal, respectively, and
wherein a timing of the first write command signal and a timing of the second write command signal is synchronized with a delay amount of the write leveling signal.

17. The memory device of claim 16, wherein the write leveling pulse signal is the first write command signal or the second write command signal.

18. The memory device of claim 1, wherein the memory device is configured to provide the host device with information about the number of locations on the data strobe signal path, at which data strobe signals are received.

19. An operating method of a memory device, the method comprising:
performing, at the memory device, a first write leveling operation to align a timing between a clock signal and a data strobe signal received from a host device; and
performing, at the memory device, a second write leveling operation to align a timing between an internal clock signal path through which the clock signal is transferred and an internal data strobe signal path through which the data strobe signal is transferred,
wherein the second write leveling operation is performed based on internal data strobe signals obtained at two or more locations on the internal data strobe signal path.

20. A memory module comprising:
a plurality of memory devices each configured to receive a data signal and a data strobe signal from a host device; and
a register clock driver configured to receive a clock signal from the host device and to provide the clock signal to the plurality of memory devices,
wherein each of the plurality of memory devices is configured to:
perform a first write leveling operation to align a timing of the clock signal provided from the register clock driver and a timing of the data strobe signal provided from the host device; and
perform a second write leveling operation to align a timing between an internal clock signal path through which the clock signal is transferred and an internal data strobe signal path through which the data strobe signal is transferred, and
wherein the second write leveling operation is performed based internal data strobe signals obtained at two or more locations on the internal data strobe signal path.
